(19) United States
(12) Patent Application Publication
(10) Pub. No.: US 2014/0311556 A1
(43) Pub. Date: Oct. 23, 2014

(54) FLEXIBLE LOW MODULUS PHOTOVOLTAIC BUILDING SHEATHING MEMBER

(71) Applicant: Dow Global Technologies LLC, Midland, MI (US)

(72) Inventors: Jie Feng, Midland, MI (US); Keith L. Kauffmann, Ypsilanti, MI (US); Kwanho Yang, Midland, MI (US); Hua Liu, Midland, MI (US); Jeffrey D. Zawisza, Midland, MI (US); Leonardo C. Lopez, Midland, MI (US)

(73) Assignee: Dow Global Technologies LLC, Midland, MI (US)

(21) Appl. No.: 14/355,667

(22) PCT Filed: Nov. 9, 2012
(86) PCT No.: PCT/US2012/064363

§ 371 Date: May 1, 2014

Related U.S. Application Data
(60) Provisional application No. 61/559,815, filed on Nov. 15, 2011.

(51) Int. Cl. H01L 31/042

(52) U.S. Cl. CPC H01L 31/0422
USPC 136/251

(57) ABSTRACT

The present invention is premised upon -m improved photovoltaic building sheathing member (“PV device”), more particularly to a flexible low modulus photovoltaic building sheathing member, the member comprising: a flexible photovoltaic cell assembly, a body portion comprised of a body material and connected to a; peripheral edge segment of the photovoltaic cell assembly, wherein the body portion has a cross-sectional area of at least 35 mm² within 1 cm on at least 95 percent of points along the peripheral edge segment: wherein the body material comprises a composition having a modulus of 5 to 200 MPa between a temperature of −40 to 85° C., with a coefficient of thermal expansion (GTE) below 100×10⁻⁶/° C., and the body portion exhibiting a warpage value of less than 15 mm.

This invention was made with U.S. Government support under contract DE-FC36-07G01754 awarded by the Department of Energy. The U.S. Government has certain rights in this invention.

### FIELD OF THE INVENTION

The present invention relates to an improved photovoltaic device (“PVD” or “PV Device”), more particularly to an improved flexible photovoltaic device (building sheathing member) with a multilayered photovoltaic cell assembly and a body portion joined at an interface region.

### BACKGROUND

Efforts to improve PV devices, particularly those devices that are integrated into building structures (e.g. roofing shingles or exterior wail coverings), to be used successfully, should satisfy a number of criteria. The PV device should be durable (e.g. long lasting, sealed against moisture and other environmental conditions) and protected from mechanical abuse over the desired lifetime of the product, preferably at least 10 years, more preferably at least 25 years. The device should be easily installed (e.g. installation similar to conventional roofing shingles or exterior wall coverings) or replaced (e.g. if damaged). It may be desirable to choose materials and components, along with design features that aid in meeting the desired durability requirements such as being free of deformations (warpage) that would impair performance and/or aesthetics.

To make this full package desirable to the consumer, and to gain wide acceptance in the marketplace, the system should be inexpensive to build and install. This may help facilitate lower generated cost of energy, making PV technology more competitive relative to other means of generating electricity.

Existing art systems for PV devices may allow for the device to be directly mounted to the building structure or they may fasten the devices to battens, channels or “rails” (“stand-offs”) above the building exterior (e.g. roof deck or exterior cladding). These systems may be complicated, typically do not install like conventional cladding materials (e.g. roofing shingles or siding) and, as a consequence, may be expensive to install. Also, they may not be visually appealing as they do not look like conventional building materials. “Stand-offs” to mount PV device every 2-4 feet may be required. Thus, installation cost can be as much or more as the cost of the article. They also may suffer from issues related to environmental conditions such as warping, fading and degradation of its physical properties.

Among the literature that can pertain to this technology include the following patent documents: WO2020151803A1; U.S.20100101627A1; WO2008137966A2; WO2007123927A2; and U.S.631028181, all incorporated herein by reference for all Purposes.

### SUMMARY OF THE INVENTION

The present invention is directed to a PV device that addresses at least one or more of the issues described in the above paragraphs.

Accordingly, pursuant to one aspect of the present invention, there is contemplated an article comprising; a flexible low modulus photovoltaic building sheathing member, the member comprising: a flexible photovoltaic cell assembly; a body portion comprised of a body material and connected to a peripheral edge segment of the photovoltaic cell assembly, wherein the body portion has a cross-sectional area of at least 35 mm² within 1 cm on at least 95 percent of points along the peripheral edge segment; wherein the body material comprises a composition having a modulus of 5 to 200 MPa between a temperature of −40 to 85° C., with a coefficient of thermal expansion (CTE) below 100×10⁻⁶/° C., and the body portion exhibiting a warpage value of less than 15 mm.

The invention may be further characterized by one or any combination of the features described herein, such as the flexible photovoltaic cell assembly has a cell height and the body portion has a body height, wherein a ratio of the cell height to the body height is at least 0.3; one or more reinforcement features are disposed on the body portion in an area adjacent to the photovoltaic cell assembly; the one or more reinforcement features comprise ribs; the ribs have a ratio of lateral spacing to rib height of at least 3.8; the ribs have a lateral spacing of less than 30.0 mm; the ribs have a rib draft of about 1 to 4 degrees per side; photovoltaic cell assembly has a modulus between 15 KPa and 20 KPa; the modulus of the body material is above 40 MPa and up to 200 MPa, the coefficient of thermal expansion (CTE) is 10×10⁻⁶/° C. to 30×10⁻⁶/° C.; the modulus of the body material is between 5 and 40 MPa and the coefficient of thermal expansion (CTE) is between 50×10⁻⁶/° C. and about 100×10⁻⁶/° C.; the CTE range of the body material composition when the modulus is above 40 MPa and up to 200 MPa is determined by a formula: CTE=a±(b+c×warpage)^{1/2} and the acceptable warpage value is set to an upper value and then to a lower value and solving for CTE for each respective value and including a plurality of constants: a, b, and c, further wherein constant a ranges in value from −106.0 to 118.0, constant b ranges in value from −18550 to 18585, and constant c ranges in value from 144.5 to 966.0; and the CTE range of the body material composition when the modulus is above 5 MPa and up to 40 MPa is determined by a formula: CTE=a×Warpage+b×E+c and the acceptable warpage value is set to an upper value and then to a lower value and solving for CTE for each respective value and including a plurality of constants: a, b, c, and E, further wherein constant a ranges in value from about 9.75 to 10.75, constant b ranges in value from 1.25 to 2.5, constant c ranges in value from 44.5 to 83.25, and constant E ranges in value from 10.5 to 32.0. The equations yield a CTE of N×10⁻⁶/° C., where N is variable.

It should be appreciated that the above referenced aspects and examples are Non-limiting, as others exist within the present invention, as shown and described herein.

### DESCRIPTION OF THE DRAWINGS

FIG. 1 illustrates a photovoltaic device of the invention.

FIG. 1A shows a device of the invention which exhibits warpage while disposed on a structure.

FIG. 2A illustrates an exploded view of a multilayer photovoltaic device.

FIG. 2B illustrates another exploded view of a multilayer photovoltaic device.

FIG. 3 shows exemplary materials useful for different layers of a photovoltaic Device.

FIG. 4 shows a connector useful for connecting adjacent photovoltaic structures together.

FIG. 5 shows the side of a photovoltaic device adapted to be placed on a structure and a number of cutaway views of the structure, 5A to 5D.

FIG. 6 shows a system useful for performing a bend test on a photovoltaic device.

### DETAILED DESCRIPTION OF THE PREFERRED EMBODIMENT

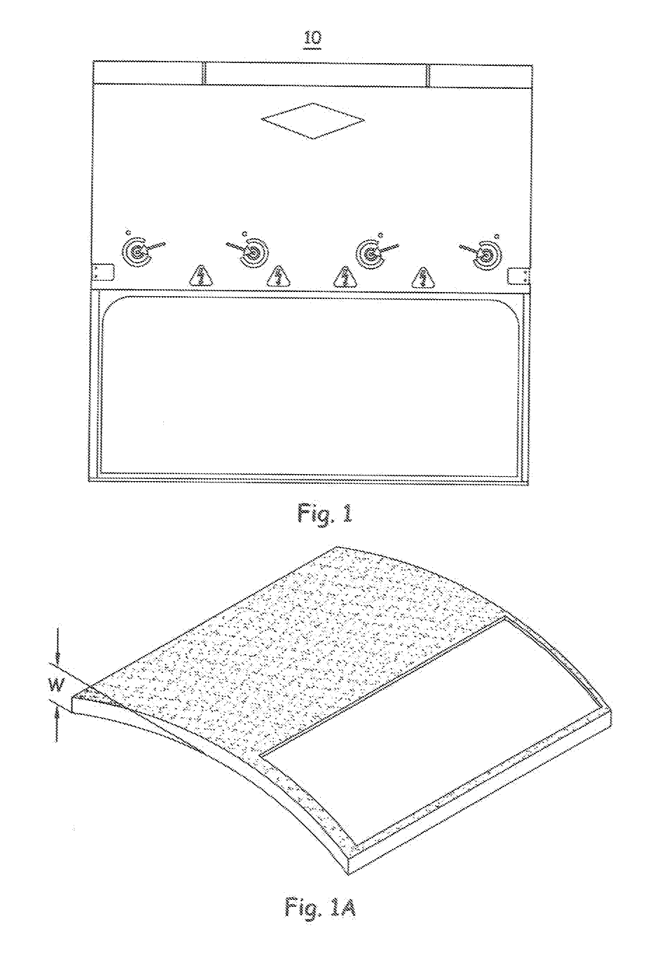

The present invention relates to an improved photovoltaic device 10 (hereafter “PV device”), as illustrated in FIG. 1, can be described generally as an assembly of a number of components and component assemblies that functions to provide electrical energy when subjected to solar radiation (e.g. sunlight). Of particular interest and the main focus of the present disclosure is an improved PV device 10 that includes at least a multilayered photovoltaic cell assembly 100 (hereafter “MPCA”) joined to a body portion 200. In a preferred embodiment, the PV device is formed by taking the MPCA (and potentially other components and assemblies such as connector components) and forming (e.g. via injection molding) the body portion about at least portions the MPCA. It is contemplated that the relationships (e.g. at least the geometric properties and the material properties) between the components and component assemblies are surprisingly important in solving one or more the issues discussed in the background section above, such as warpage. Warpage “W” can be defined as an uplift (from what would be flat) of the any part of the device 10, for example as shown in FIG. 1A, particularly when installed on a structure. Warpage is measured in millimeters as the distance between the surface of the building structure and a portion of the photovoltaic device adapted to be placed flat on the building structure which is not disposed on the building structure. It is contemplated that the maximum amount of warpage that may be acceptable in a device is less than about 20 mm, more preferably less than about 15 mm and most preferably less than about 10 or 5 mm, where ultimately no warpage would be ideal. Of particular interest is where the PV device 10 is utilized for what is commonly known as Building-Integrafed Photovoltaics, or BIPV. Each of the components and component assemblies and their relationships are disclosed in greater detail and specificity in the following paragraphs.

### Multilayered Photovoltaic Cell Assembly (MPCA) 100

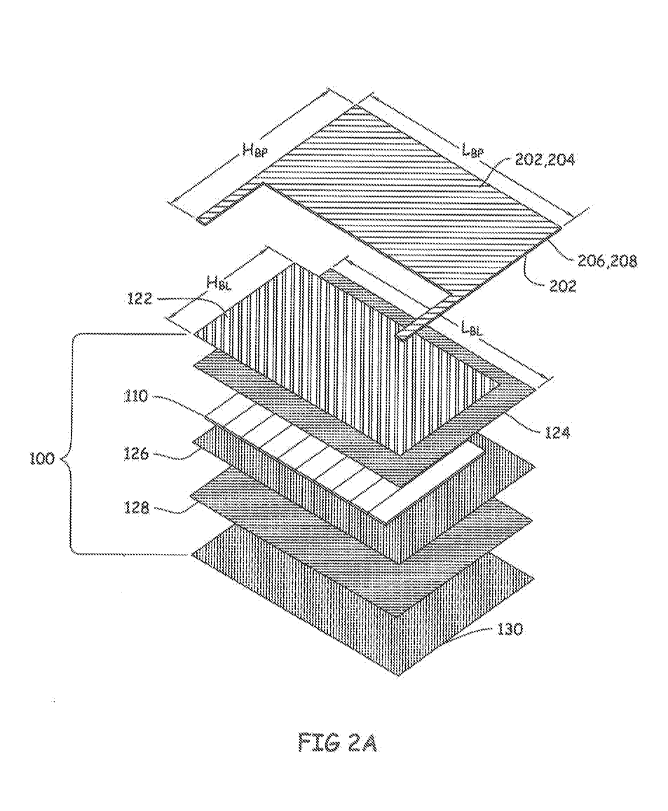

It is contemplated that the MPCA 100 (also known as the flexible photovoltaic cell assembly) may be a compilation of numerous layers and components/assemblies, for example as disclosed in currently pending international patent application No. PCT/US09/042496, incorporated herein by reference. The MPCA contains at least a top barrier layer 122 and a photovoltaic cell layer 110 (generally located inboard of the peripheral edge of the barrier layer 122). It is contemplated that the MPCA 100 may also contain other layers, such as encapsulant layers and other protective layers. Illustrative examples are shown in the figures and are discussed below. Exploded views of exemplary MPCAs 100 are shown in FIGS. 2A and 2B.

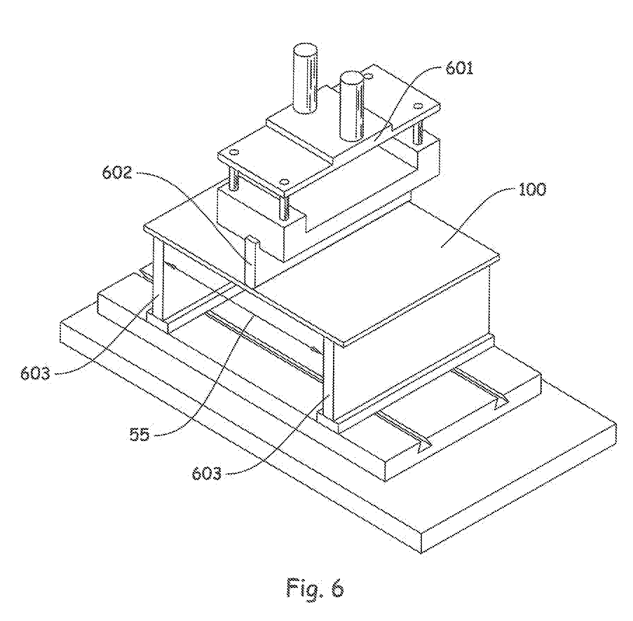

Functionally, these encapsulant layers and other protective layers may include a number of distinct layers that each serve to protect and/or connect the MCPA 100 together. Each preferred layer is described in further detail below, moving from the “top”(e.g. the layer most exposed to the elements) to the “bottom” (e.g. the layer most closely contacting the building or structure). In general each preferred layer or sheet may be a single layer or may itself comprise sub layers. It is preferred that the MCPA 100 is flexible. For terms of this disclosure, it is preferred that “flexible” may be defined to mean that the MCPA 100, and ultimately the PV device 10 is more flexible or less rigid than the substrate (e.g. building structure) to which it is attached. It is more preferred that “flexible” may be defined as that the MCPA 100, and ultimately the PV device 10 can bend about a 1 meter diameter cylinder without a decrease in performance or critical damage. It is even more preferred that a flexible device 10 would experience greater than 50 mm (˜2 inches) of deflection under a load of 100 Kg with a support span SS of about 560 mm without a decrease in performance, for example as presented as a three point bend test utilising the apparatus as shown in FIG. 6. Shown is the multilayered photovoltaic cell assembly 100 disposed on supports 603. The support span 55 is the distance between the supports 803. Also shown is the load cell 601 and the center load plate 602.

As shown in the figures, the MCPA has a height (H_{BL}) and a width (L_{BL}), these may be as little as 10 cm and as much as 100 cm or more, respectively, although generally are smaller than with width/length of the body 200.

### Top Barrier Layer 122

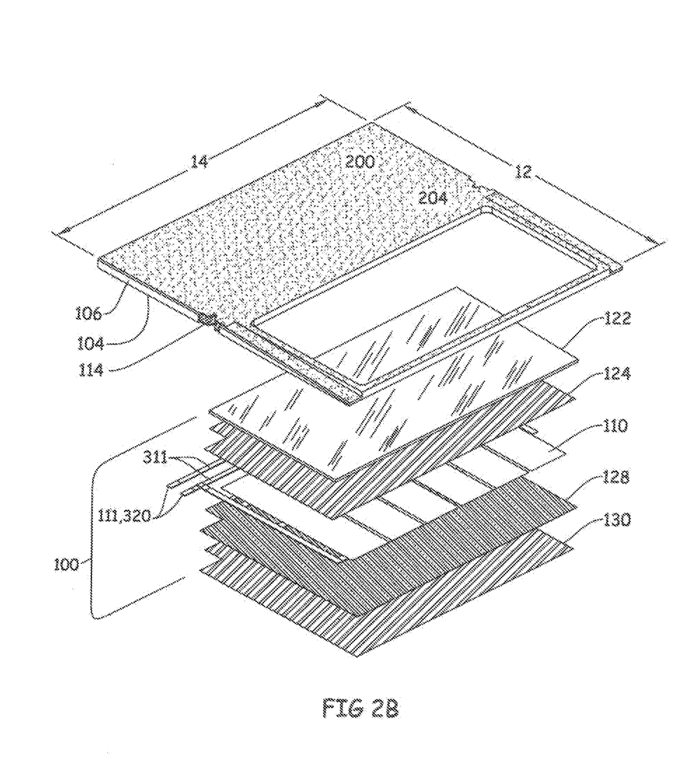

The top barrier layer 122 may function as an environmental shield for the MPCA 100 generally, and more particularly as an environmental shield for at least a portion of the photovoltaic cell layer 110. The top barrier layer 122 is preferably constructed of a transparent or translucent material that allows light energy to pass through to the photoactive portion of the photovoltaic cell layer 110. This material should be flexible (e.g. a thin polymeric film or a multi-layer film), thus allowing the MPCA to bend easily while not being damaged. The material may also be characterized by being resistant to moisture/particle penetration or build up. The top barrier layer 122 may also function to filter certain wavelengths of light such that preferred wavelengths may readily reach the photovoltaic cells. In a preferred embodiment, the top barrier layer 122 material will also range in thickness from about 70 um to about 700 um. Other physical characteristics, at least in the case of a film or multilayer films, may include: a tensile strength of greater than 20 MPa (as measured by JIS K7127); tensile elongation of 1% or greater (as measured by JIS K7127); and/or a water absorption (23° C., 24 hours) of 0.05% or less (as measured per ASTM D570); and/or a coefficient of thermal expansion (“CTE”) of about 10×10⁻⁶/° C. to as much as 350×10⁻⁶/° C. and a visible light transmission of at least about 85%, preferably about at least 87%, more preferably at least about 90%. In one preferred embodiment, the top barrier layer 122, as shown in FIG. 3, may be comprised of a number of layers. In this preferred embodiment, the layers include a Fluoropolymer, a bonding layer (for example, using the same material as the below encapsulant layers), and a polyethylene terephthalate (PET)/AlOₓ with planarizing Layer(s) top layer, such as commercially available TechniMet FG300.

### First Encapsulant Layer 124

In one example, a first encapsulant layer 124 may be disposed below the top barrier layer 122 and generally above the photovoltaic cell layer 110. If is contemplated that the first encapsulant layer 124 may serve as a bonding mechanism, helping hold the adjacent layers together. It should also allow the transmission of a desired amount and type of light energy to reach the photovoltaic cell 110. The first encapsulant layer 124 may also function to compensate for irregularities in geometry of the adjoining layers or translated though those layers (e.g. thickness changes). It also may serve to allow flexure and movement between layers due to temperature change and physical movement and bending. In a preferred embodiment, first encapsulant layer 124 may consist essentially of an adhesive film or mesh, preferably an EVA (ethylene-vinylacetate), thermoplastic polyolefin or similar material. The preferred thickness of this layer ranges from about 0.1 mm to 1.0 mm, more preferably from about 0.2 mm to 0.8 mm, and most preferably from about 0.25 mm to 0.5 mm.

### Photovoltaic Cell Layer 110

The photovoltaic cell layer 110 contemplated in the present invention may be constructed of any number of known photovoltaic cells commercially available or may be selected from some future developed photovoltaic cells. These cells function to translate light energy into electricity. The photoactive portion of the photovoltaic cell is the material which converts light energy to electrical energy. Any material known to provide that function may be used including, amorphous silicon, CdTe, GaAs, dye-sensitized solar cells (so-called Gratezel cells), organic/polymer solar cells, or any other material that converts sunlight into electricity via the photoelectric effect. However, the photoactive layer is preferably a layer of IB-IIIA-chalcogenide, such as IB-IIIA-selenides, IB-IIIA-sulfides, or IB-IIIA-selenide sulfides. More specific examples include copper indium selenides, copper indium gallium selenides, copper gallium selenides, copper indium sulfides, copper indium gallium sulfides, copper gallium selenides, copper indium sulfide selenides, copper gallium sulfide selenides, and copper indium gallium sulfide selenides (all of which are referred to herein as CIGSS). These can also be represented by the formula Culn(1−x)GaxSe(2−y)Sy where x is 0 to 1 and y is 0 to 2. The copper indium selenides and copper indium gallium selenides are preferred. Additional electroactive layers such as one or more of emitter (buffer) layers, conductive layers (e.g. transparent conductive layers) and the like as is known in the art to be useful in CIGSS based cells are also contemplated herein. These cells may be flexible or rigid and come in a variety of shapes and sizes, but generally are fragile and subject to environmental degradation. In a preferred embodiment, the photovoltaic cell assembly 110 is a cell that can bend without substantial cracking and/or without significant loss of functionality. Exemplary photovoltaic cells are taught and described in a number of US patents and publications, including U.S. Pat. No. 3,767,471, U.S. Pat. No. 4,465,575, U.S.20050011550 A1, EP841706 A2, US20070256734 a1, EP1032051A2, JP2216874, JP2143468, and JP10189924a, incorporated hereto by reference for all purposes.

The photovoltaic cell layer 110, for example as illustrated in FIG. 2B, may also include electrical circuitry, such as buss bar(s) 111 that are electrically connected to the cells, the connector assembly component(s) 300 and generally run from side to side of the PV device 10. This area may be known as the buss bar region 311.

### Second Encapsulant Layer 126

In another example of an encapsulant layer, a second encapsulant layer 126, is generally connectively located below the photovoltaic cell layer 110, although in some instances, it may directly contact the top layer 122 and/or the first encapsulant layer 124. It is contemplated that the second encapsulant layer 126 may serve a similar function as the first encapsulant layer, although it does not necessarily need to transmit electromagnetic radiation or light energy.

### Back Sheet 128

In an example of a protective layer there may be a back sheet 128 which is connectivity located below the second encapsulant layer 126. The back sheet 128 may serve as an environmental protection layer (e.g. to keep out moisture and/or particulate matter from the layers above). It is preferably constructed of a flexible material (e.g. a thin polymeric film, a metal foil, a multi-layer film, or a rubber sheet). In a preferred embodiment, the back sheet 128 material may be moisture impermeable and also range in thickness from about 0.05 mm to 10.0 mm, more preferably from about 0.1 mm to 4.0 mm, and most preferably from about 0.2 mm to 0.8 mm. Other physical characteristics may include: elongation at break of about 20% or greater (as measured by ASTM D882); tensile strength or about 25 MPa or greater (as measured by ASTM D882); and tear strength of about 70 kN/m or greater (as measured with the Graves Method). Examples of preferred materials include aluminum foil and Tedlar® (a trademark of Du Pont) or a combination thereof. Another preferred material is Protekt TFB from Madico (Woburn, Ma.).

### Supplemental Barrier Sheet 130

In another example of a protective layer there may be a supplemental barrier sheet 130 which is connectivity located below the back sheet 128. The supplemental barrier sheet 130 may act as a barrier, protecting the layers above from environmental conditions and from physical damage that may be caused by any features of the structure on which the PV device 10 is subjected to (e.g. For example, irregularities in a roof deck, protruding objects or the like). It is contemplated that this is an optional layer and may not be required. It is also contemplated that this layer may serve the same functions as the body portion 200. In a preferred embodiment, the supplemental barrier sheet 130 material may be at least partially moisture impermeable and also range in thickness from about 0.25 mm to 10.0 mm, more preferably from about 0.5 mm to 2.0 mm, and most preferably from 0.8 mm to 1.2 mm. It is preferred that this layer exhibit elongation at break of about 20% or greater (as measured by ASTM D882); tensile strength or about 10 MPa or greater (as measured by ASTM D882); and tear strength of about 35 kN/m or greater (as measured with the Graves Method). Examples of preferred materials include thermoplastic polyolefin (“TPO”), thermoplastic elastomer, olefin block copolymers (“OBC”), natural rubbers, synthetic rubbers, polyvinyl chloride, and other elastomeric and plastomeric materials. Alternately the protective layer could be comprised of more rigid materials so as to provide additional roofing function under structural and environmental (e.g. wind) loadings. Additional rigidity may also be desirable so as to improve the coefficient of thermal expansion of the PV device 10 and maintain the desired dimensions during temperature fluctuations. Examples of protective layer materials for structural properties include polymeric materials such polyolefins, polyester amides, polysulfone, acetal, acrylic, polyvinyl chloride, nylon, polycarbonate, phenolic, polyetheretherketone, polyethylene terephthatate, epoxies, including glass and mineral filled composites or any combination thereof.

The above described layers may be configured or stacked in a number of combinations, but it is preferred that the top barrier layer 122 is the top layer. Additionally, it is contemplated that these layers may be integrally joined together via any number of methods, including but not limited to: adhesive joining; heat or vibration welding; over-molding; or mechanical fasteners.

### Body Portion 200

It is contemplated that the body portion 200 may be a compilation of components/assemblies, but is preferably generally a polymeric article that is formed by injecting a polymer (or polymer blend) into a mold (with or without inserts such as the MPCA 100 or the other component(s) (e.g. connector component)—discussed later in the application), for example as disclosed in currently pending International patent application No. PCT/US09/042496, incorporated herein by reference. The body portion 200 functions as the main structural carrier for the PV device 10 and should be constructed in a manner consistent with this. For example, it can essentially function as a plastic framing material.

It is contemplated that the compositions have flexural modulus that ranges from about 5 MPa to as high as 200 MPa. The flexural modulus of compositions were determined by test method ASTM D790-07 (2007) using a test speed of 2 mm/min. It is contemplated that the compositions that make up the body portion 200 also exhibit a coefficient of thermal expansion (“body CTE”) of about 10×10⁻⁶/° C. to 100×10⁻⁶/° C. Matching the CTE's between the composition comprising the body portion 200 and the MPCA may be important for minimizing thermally-induced stresses on the BIPV device during temperature changes, which can potentially result in undesirable warpage of the device (e.g. above about 15 mm).

In a preferred embodiment, the body support portion 200 may comprise (be substantially constructed from) a body material. This body material may be a filled or unfilled moldable plastic (e.g. polyolefins, acrylonitrile butadiene styrene (SAN), hydrogenated styrene butadiene rubbers, polyester amides, polyether imide, polysulfone, acetal, acrylic, polyvinyl chloride, nylon, polyethylene terephthatate, polycarbonate, thermoplastic and thermoset polyurethanes, synthetic and natural rubbers, epoxies, SAN, Acrylics, polystyrene, or any combination thereof). Fillers (preferably up to about 50% by weight) may include one or more of the following: colorants, fire retardant (FR) or ignition resistant (IR) materials, reinforcing materials, such as glass or mineral fibers, surface modifiers. Plastic may also include antioxidants, release agents, blowing agents, and other common plastic additives.

In a preferred embodiment, the body material (composition(s)) has a melt flow rate of at least 5 g/10 minutes, more preferably at least 10 g/10 minutes. The melt flow rate is preferably less than 100 g/10 minutes, more preferably less than 50 g/10 minutes and most preferably less than 30 g/10 minutes. The melt flow rate of compositions were determined by test method ASTM D1238-04, “REV C Standard Test Method for Melt Flow Rates of Thermoplastics by Extrusion Plastometer”, 2004 Condition L (230° C./2.16 Kg). Polypropylene resins used in this application also use this same test method and condition. The melt flow rate of polyethylene and ethylene—α-olefin copolymers in this invention are measured using Condition E (190° C./2.16 Kg), commonly referred to as the melt index.

In all embodiments, the compositions have flexural modulus that ranges from about 5 MPa to as high as 200 MPa. The flexural modulus of compositions were determined by test method ASTM D790-07 (2007) using a test speed of 2 mm/min. It is contemplated that the compositions that make up the body portion 200 also exhibit a coefficient of thermal expansion (“body CTE”) of about 10×10⁻⁶/° C. to 100×10⁻⁶/° C.

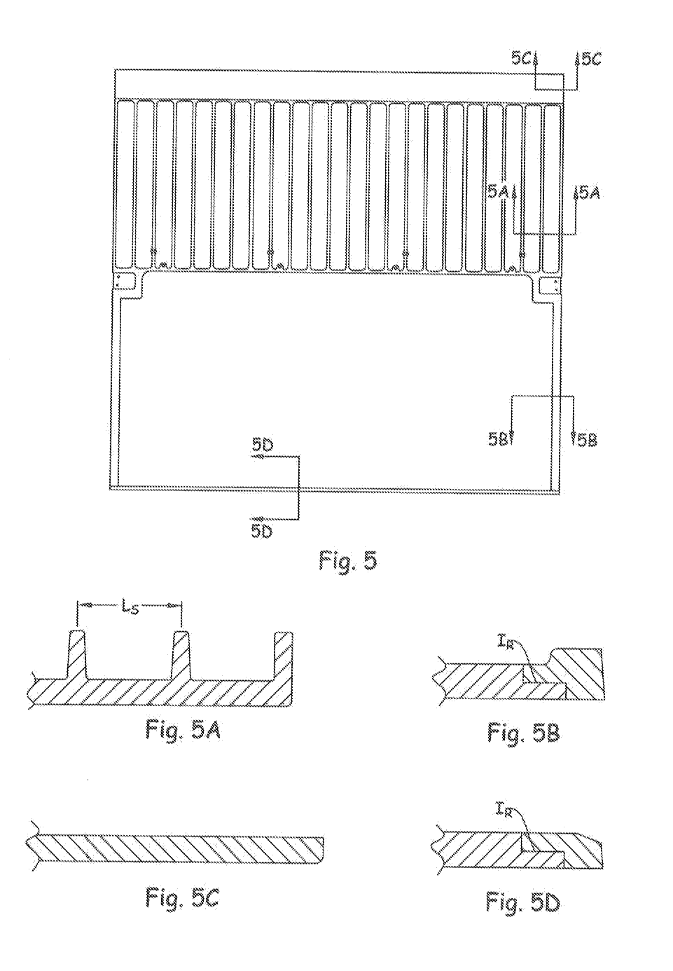

It is contemplated that the body portion 200 may be any number of shapes and sizes. For example, if may be square, rectangular, triangular, oval, circular or any combination thereof. The body portion 200 may also be described as having a height “H_{SP}” and a width “L_{SP}”, for example as labeled in FIG. 2A and may be as little as 10 cm and as much as 200 cm or more, respectively. It may also have a thickness (T) that may range from as little as about 5 mm to as much as 20 mm or more and may vary in different area of the body portion 200. Preferably, the body portion 200 can be described as having a body lower surface portion 202, body upper surface portion 204 and a body side surface portion 206 spanning between the upper and lower surface portions and forming a body peripheral edge 208. It is also contemplated that the cross-sectional area of the body portion, at least within about 1 cm of the edge of the device 10, and on at least 95 percent of points along a peripheral edge segment of the MCPA 100, is at least about 35 mm². The recited cross-sectional area is the cross-sectional area of the body portion from the peripheral edge of the body 200 toward the laminate structure 100. Preferably the cross-sectional portion is measured perpendicular to the peripheral edge of the body portion. This is illustrated by FIGS. 5C and 5D.

### Connector Assembly

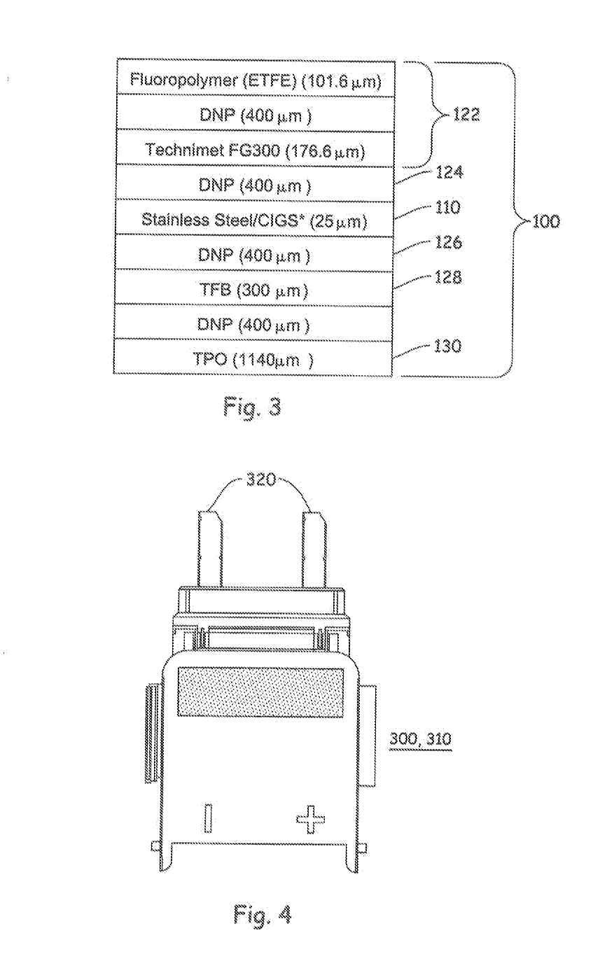

The connector assembly functions to allow for electrical communication to and/or from the PV device 10. This communication may be in conjunction with circuitry connected to the photovoltaic cell layer 110 or may just facilitate communication through and across the PV device 10 via other circuitry. The connector assembly may be constructed of various components and assemblies, and the main focus of this invention relates to the connector assembly component(s) 300 that are integral to (embedded within) the PV device. Generally, as illustrated in FIG. 4, this component 300 comprises a polymeric housing 310 and electrical leads 320 protruding into the PV device 10, although other configurations are contemplated. Examples of preferred materials that make up the housing 310 include: Polymeric compounds or blends of PBT (Polybutylene Terephthalate), PPO (Polypropylene Oxide), PPE (Polyphenylene ether), PPS (Polyphenylene sulfide), PA (Poly Amide) and PEI (polyether imide) and these can be with or without fillers of up to 65% by weight.

### Geometric and Material Property Relationships

It is believed that the choices of materials used in the construction of the PV device 10 and its constituent components and both the geometric and physical property relationships have an effect on overall performance of the system (e.g. durability, aesthetics, and ease of assembly of multiple PV devices together). Balancing the needs of ease of manufacture, costs and/or product performance requirements may drive unique material choices and component design. The present invention contemplates these factors and provides a unique solution to achieve a desired result.

It is contemplated that if may be desirous to match physical properties as much as feasible of the various components such that the complete system can work in harmony (e.g. all or most components constructed from similar materials or material families). Where this cannot be achieved fully, it is contemplated that unique geometric design features may be needed. Of particular interest are the relationship of choice of material properties of the body portion 200 and the MCPA 100 and the geometric relationship to each other. It is contemplated that the device 10 may have a height 12 and a width 14 of that can be as small as about 25 cm to as large as 200 cm, or anywhere in-between. In a preferred embodiment, the height 12 and width 14 have a minimum height to width ratio of about 1, more preferably about 0.5 and most preferably about at least 0.3.

### MPCA and Body Relationships

This section concentrates on certain aspects of the relationships between the MCPA 100 and the body portion 200. Several illustrative examples and preferred embodiments are detailed herein. One skilled in the art should realize that these examples should not be limiting and the present invention contemplates other potential configurations.

In a first illustrative example, a flexible low modulus photovoltaic building sheathing member may include: a flexible photovoltaic cell assembly; a body portion comprised of a body material and connected to a peripheral edge segment (e.g. at an interface region I_{R}) of the photovoltaic cell assembly, wherein the body portion has a cross-sectional area of at least 35 mm² within 1 cm on at least 95 percent of points along the peripheral edge segment; and the body material comprises a composition having a modulus of 5 to 200 MPa between a temperature of −40 to 85° C.; with a coefficient of thermal expansion (CTE) below 100×10⁻⁶/° C., and the body portion exhibiting a warpage value of less than 15 mm. It should be noted that the MCPA is generally smaller than the body portion and is surrounded by the body portion along its peripheral edge (e.g. its thickness). In one preferred embodiment, the H_{BL} (cell height) of the MCPA is at least about half that of the H_{SP} (body height) in other words, the ratio of H_{BL} to H_{SP} is at least about 0.5, more preferably at least about 0.4 and most preferably about at least 0.3. The ratio of the height H_{BL} of the multilayered photovoltaic cell assembly to its width L_{BL} can impact the tendency of the photovoltaic device to warp. This ratio may be chosen to reduce the tendency of the device to warp. Preferably the ratio H_{BL}/L_{BL} is 0.33 or greater, more preferably about 0.5 or greater and most preferably about 1.0 or greater. The upper limit for this ratio is practicality. Preferably the ratio H_{BL}/L_{BL} is about 4.0 or less. more preferably about 3.0 or less and most preferably about 2.0 or less.

In a preferred embodiment, it is contemplated that if the composition has a modulus of about 5 MPa to as much as 40 MPa, then it is preferred that the body CTE should range between about 50×10⁻⁶/° C. and about 100×10⁻⁶/° C. It is also contemplated that if the composition has a modulus above 40 MPa to about 200 MPa, then the preferred body CTE should range between about 10×10⁻⁶/° C. to about 30×10⁻⁶/° C.

In a second illustrative example, the flexible low modulus photovoltaic building sheathing member also includes one or more reinforcement features that are disposed on the body portion in an area adjacent to the photovoltaic cell assembly. The reinforcement features function to support the flexible photovoltaic cell assembly of the photovoltaic device while on a structure and to prevent cracking or damage to the multilayer photovoltaic assembly if pressure is applied to it while affixed to a building structure, for instance due to a person standing on the photovoltaic device. Reinforcement structures are utilized to provide reinforcement and support without requiring a solid layer interfacing with the building structure, thereby reducing the weight and cost of the photovoltaic device. Preferably, the reinforcements allow water to flow under the photovoltaic device to the edge of the building structure. Any reinforcement structures that perform these functions may be utilized, for instance projections from the body portion toward building structure, wherein the projections can be arranged randomly or in any pattern such that the recited functions are achieved. The projections can be continuous or discontinuous. If continuous the projections can be in any pattern which achieves the function, for instance in the form of ribs. The ribs can be disposed in any alignment consistent with the function. The ribs can be disposed in a parallel alignment, preferably aligned to allow water to flow down the building structure. Alternatively, the ribs can be disposed in different directions and the ribs may intersect one another to form a pattern, for instance a honeycomb type of pattern.

In a preferred embodiment, it is contemplated that these reinforcement features are in the form of ribs, as shown in FIG. 5. It is preferred that the ribs have a rib draft of about 1 to 4 degrees per side, a maximum thickness of the rib at its base of about 3.3 mm and a minimum rib thickness of 1.5 mm. Additionally, it is contemplated that the maximum rib height is about 7.0 mm.

In another preferred embodiment, the ribs have a ratio of lateral spacing to rib height of at least 3.8 and even more preferably, the ribs have a lateral spacing (L_{S}) of less than about 30.0 mm.

In a third illustrative example, the flexible low modulus photovoltaic building sheathing member may be configured as in the first or second illustrative example. In this example, the relationship between the body material 200 and the MCPA 100 may be expressed in the following formulae. It is contemplated that the CTE range of the body material composition within the low modulus range (5-40 MPa) is determined by a formula: CTE=a×Warpage+b×E+c, wherein the acceptable warpage value is set to an upper value and then to a lower value and solving for CTE for each respective value and including a plurality of constants: a, b, c, and E, further wherein constant a ranges in value from about 9.75 to 10.75, constant b ranges in value from 1.25 to 2.5, constant c ranges in value from 44.5 to 83.25, and constant E ranges in value from 10.5 to 32.0. It is also contemplated that the CTE range of the body material composition within the higher range (above 40 to 200 MPa), the CTE range is determined by a formula: CTE=a±(b+c×warpage)^{1/2}, wherein the acceptable warpage value is set to an upper value and then to a lower value and solving for CTE for each respective value and including a plurality of constants: a, b, and c, further wherein constant a ranges in value from −106.0 to 118.0, constant b ranges in value from −18550 to 18585, and constant c ranges in value from 144.5 to 966.0.

Unless stated otherwise, dimensions and geometries of the various structures depicted herein are not intended to be restrictive of the invention, and other dimensions or geometries are possible. Plural structural components can be provided by a single integrated structure. Alternatively, a single integrated structure might be divided into separate plural components. In addition, while a feature of the present invention may have been described in the context of only one of the illustrated embodiments, such feature may be combined with one or more other features of other embodiments, for any given application, it will also be appreciated from the above that the fabrication of the unique structures herein and the operation thereof also constitute methods in accordance with the present invention.

The preferred embodiment of the present invention has been disclosed. A person of ordinary skill in the art would realize however, that certain modifications would come within the teachings of this invention. Therefore, the following claims should be studied to determine the true scope and content of the invention.

Any numerical values recited in the above application include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, preferably from 20 to 80, more preferably from 30 to 70, it is intended that values such as 15 to 85, 22 to 68, 43 to 51, 30 to 32 etc. are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the highest value enumerated are to be considered to be expressly stated in this application in a similar manner.

Unless otherwise stated, ail ranges include both endpoints and all numbers between the endpoints. The use of “about” or “approximately” in connection with a range applies to both ends of the range. Thus, “about 20 to 30” is intended to cover “about 20 to about 30”, inclusive of at least the specified endpoints.

The disclosures of all articles and references, including patent applications and publications, are incorporated by reference for all purposes.

The term “consisting essentially of” to describe a combination shall include the elements, ingredients, components or steps identified, and such other elements ingredients, components or steps that do not materially affect the basic and novel characteristics of the combination.

The use of the terms “comprising” or “including” describing combinations of elements, ingredients, components or steps herein also contemplates embodiments that consist essentially of the elements, ingredients, components or steps.

Plural elements, ingredients, components or steps can be provided by a single integrated element, ingredient, component or step. Alternatively, a single integrated element, ingredient, component or step might be divided into separate plural elements, ingredients, components or steps. The disclosure of “a” or “one” to describe an element, ingredient, component or step is not intended to foreclose additional elements, ingredients, components or steps. All references herein to elements or metals belonging to a certain Group refer to the Periodic Table of the Elements published and copyrighted by CRC Press, Inc., 1989. Any reference to the Group or Groups shall be to the Group or Groups as reflected in this Periodic Table of the Elements using the IUPAC system for numbering groups.

1. An article comprising:
a flexible flexural low modulus photovoltaic building sheathing member, the member comprising:
a flexible photovoltaic cell assembly assembly comprising a top barrier layer which is flexible;
a body portion comprised of a body material and connected to a peripheral edge segment of the photovoltaic cell assembly, wherein the body portion has a cross-sectional area of at least 35 mm² within 1 cm on at least 95 percent of points along the peripheral edge segment;
wherein the body material comprises a composition having a flexural modulus of 5 to 200 MPa between a temperature of −40 to 85° C., with a coefficient of thermal expansion (CTE) below 100×10⁻⁶/° C., and the body portion exhibiting a warpage value of less than 15 mm.

2. The article according to claim 1, wherein the flexible photovoltaic cell assembly has a cell height and the body portion has a body height, wherein a ratio of the cell height to the body height is at least 0.3.

3. The article according to claim 1, wherein one or more reinforcement features are disposed on the body portion in an area adjacent to the photovoltaic cell assembly.

4. The article according to claim 3, wherein the one or more reinforcement features comprise ribs.

5. The article according to claim 4, wherein the ribs have a ratio of lateral spacing to rib height of at least 3.8.

6. The article according to claim 3, wherein the ribs have a lateral spacing of less than 30.0 mm.

7. The article according to claim 1, wherein the ribs have a rib draft of about 1 to 4 degrees per side.

8. The article according to claim 1, wherein photovoltaic cell assembly has a flexural modulus between 15 KPa and 20 KPa.

9. The article according to claim 1, wherein the flexural modulus of the body material is above 40 MPa and up to 200 MPa, the coefficient of thermal expansion (CTE) is 10×10⁻⁶/° C. to 30×10⁻⁶/° C.

10. The article according to claim 1, wherein the flexural modulus of the body material is between 5 and 40 MPa and the coefficient of thermal expansion (CTE) is between 50×10⁻⁶/° C. and about 100×10⁻⁶/° C.

11. The article according to claim 1, wherein the CTE range of the body material composition when the flexural modulus is above 40 MPa and up to 200 MPa is determined by a formula:
CTE=a±(b+c×warpage)^{1/2}
wherein the acceptable warpage value is set to an upper value and then to a lower value and solving for CTE for each respective value and including a plurality of constants: a, b, and c, further wherein constant a ranges in value from −106.0 to 118.0, constant b ranges in value from −18550 to 18585, and constant c ranges in value from 144.5 to 988.0.

12. The article according to claim 1, wherein the CTE range of the body material composition when the flexural modulus is above 5 MPa and up to 40 MPa is determined by a formula:
CTE=a×Warpage+b×E+c
wherein the acceptable warpage value is set to an upper value and then to a lower value and solving for CTE for each respective value and including a plurality of constants: a, b, c, and E, further wherein constant a ranges in value from about 9.75 to 10.75, constant b ranges in value from 1.25 to 2.5, constant c ranges in value from 44.5 to 83.25, and constant E ranges in value from 10.5 to 32.0.

13. The article according to Claim 1, wherein the top barrier layer comprises a thin polymeric film or a multi-layer film.
